(19) United States
(12) Patent Application Publication
(10) Pub. No.: US 2025/0254985 A1
(43) Pub. Date: Aug. 7, 2025

(54) FINFET WITH GATE-ALL-AROUND STRUCTURE INCLUDING GATE DIELECTRIC LAYER THICKER IN BURIED GATE REGION THAN IN OUTER GATE REGION

(71) Applicant: GlobalFoundries U.S. Inc., Malta, NY (US)

(72) Inventors: Hong Yu, Clifton Park, NY (US); David Charles Pritchard, Schenectady, NY (US); Navneet K. Jain, Milpitas, CA (US); Wei Ma, Clifton Park, NY (US); Romain H.A. Feuillette, Williston, VT (US)

(21) Appl. No.: 18/433,622

(22) Filed: Feb. 6, 2024

(51) Int. Cl. H01L 27/088; H01L 21/8234; H01L 29/423; H01L 29/66; H01L 29/775; H01L 29/78; H01L 29/786

(52) U.S. Cl. CPC H10D 84/834; H10D 30/014; H10D 30/024; H10D 30/43; H10D 30/6211; H10D 30/6735; H10D 30/6757; H10D 64/017; H10D 84/0142; H10D 84/0158; H10D 84/038; H10D 30/6736

(57) ABSTRACT

A structure including a first fin-type field effect transistor (finFET) in a first semiconductor fin. The first finFET includes a channel region between a first source/drain (S/D) region and a second S/D region; and a gate all around (GAA) structure. The GAA structure includes an outer gate region over the channel region and a buried gate region under of the channel region and extending between the first S/D region and the second S/D region. The outer gate region and the buried gate region each include a gate metal layer and a gate dielectric layer. The gate dielectric layer is thicker in the buried gate region than in the outer gate region.

### BACKGROUND

Embodiments of the disclosure relate generally to integrated circuit (IC) structures. More particularly, the disclosure relates to structures and methods to provide gate-all-around structures with thick dielectric layers.

Integrated circuit (IC) chips have billions of devices thereon, such as transistors, capacitors, and resistors. As devices shrink, device reliability is adversely affected by diminishing proximity between subcomponents in individual devices, such as between gates and channels in transistors. One issue created by shrinking dimensions is hot carrier injection (HCI), which is when charge carriers (i.e., electrons or holes) gain sufficient energy to overcome a potential barrier at the interface of two materials (e.g., at the interface of a gate conductor and a dielectric thereunder), which damages regions thereunder and causes devices to breakdown. Therefore, reducing HCI in devices improves longevity and reliability of devices formed on IC chips.

### SUMMARY

An aspect of the disclosure includes a structure, comprising: a first fin-type field effect transistor (finFET) in a first semiconductor fin, the first finFET including: a channel region between a first source/drain (S/D) region and a second S/D region; and a gate all around (GAA) structure including: an outer gate region over the channel region and a buried gate region under of the channel region and extending between the first S/D region and the second S/D region, the outer gate region and the buried gate region each including a gate metal layer and a gate dielectric layer, wherein the gate dielectric layer is thicker in the buried gate region than in the outer gate region.

Another aspect of the disclosure includes a structure, comprising: a first fin-type field effect transistor (finFET) in a first semiconductor fin, the first finFET including: a single channel region between a first source/drain (S/D) region and a second S/D region; a gate all around (GAA) structure including an outer gate region over the channel region and a buried gate region under of the channel region and extending between the first S/D region and the second S/D region, the outer gate region and the buried gate region each including a gate metal layer and a gate dielectric layer, wherein the gate dielectric layer is thicker in the buried gate region than in the outer gate region, and a second finFET in a second semiconductor fin adjacent the first finFET.

Another aspect of the disclosure includes a method, comprising: forming a first semiconductor fin; and forming a first fin-type field effect transistor (finFET) in the first semiconductor fin, including: forming a channel region between a first source/drain (S/D) region and a second S/D region; forming a gate all around (GAA) structure, including: forming an outer gate region over the channel region and a buried gate region under of the channel region and extending between the first S/D region and the second S/D region, forming a gate dielectric layer surrounding the channel region, wherein the gate dielectric is thicker in the buried gate region than in the outer gate region, and forming a gate metal layer surrounding the gate dielectric layer about the channel region.

It should be noted that all aspects, examples, and features of disclosed embodiments mentioned herein can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a partial perspective view of a structure according to embodiments of the disclosure.

FIG. 2 shows a partial perspective cross-sectional view of a structure according to embodiments of the disclosure.

FIG. 3A shows a partial perspective cross-sectional view of a structure according to embodiments of the disclosure.

FIG. 3B shows a cross-sectional view of a structure along view line 2-2 in FIG. 1 according to embodiments of the disclosure.

FIG. 4A shows a partial perspective cross-sectional view of a structure according to embodiments of the disclosure.

FIG. 4B shows a cross-sectional view of a structure according to embodiments of the disclosure.

FIG. 5A shows a partial perspective cross-sectional view of a structure according to embodiments of the disclosure.

FIG. 5B shows a cross-sectional view of a structure according to embodiments of the disclosure.

FIG. 6A shows a cross-sectional view of forming a structure according to embodiments of the disclosure.

FIG. 6B shows a cross-sectional view of forming a structure according to embodiments of the disclosure.

FIG. 7A shows a cross-sectional view of forming a structure according to embodiments of the disclosure.

FIG. 7B shows a cross-sectional view of forming a structure according to embodiments of the disclosure.

FIG. 8A shows a cross-sectional view of forming a structure according to embodiments of the disclosure.

FIG. 8B shows a cross-sectional view of forming a structure according to embodiments of the disclosure.

FIG. 9A shows a cross-sectional view of forming a structure according to embodiments of the disclosure.

FIG. 9B shows a cross-sectional view of forming a structure according to embodiments of the disclosure.

FIG. 10A shows a cross-sectional view of forming a structure according to embodiments of the disclosure.

FIG. 10B shows a cross-sectional view of forming a structure according to embodiments of the disclosure.

FIG. 10C shows a cross-sectional view of forming a structure according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B,” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a structure including a first fin-type field effect transistor (finFET) in a first semiconductor fin. The first finFET includes a channel region between a first source/drain (S/D) region and a second S/D region; and a gate all around (GAA) structure. The GAA structure includes an outer gate region over the channel region and a buried gate region under of the channel region and extending between the first S/D region and the second S/D region. The outer gate region and the buried gate region each include a gate metal layer and a gate dielectric layer. The gate dielectric layer is thicker in the buried gate region than in the outer gate region. By including a GAA structure with a gate dielectric layer thicker in the buried gate region than in the outer gate region, the structure is less prone to hot carrier injection breakdown in the channel region, and will therefore have improved longevity, reliability, and performance.

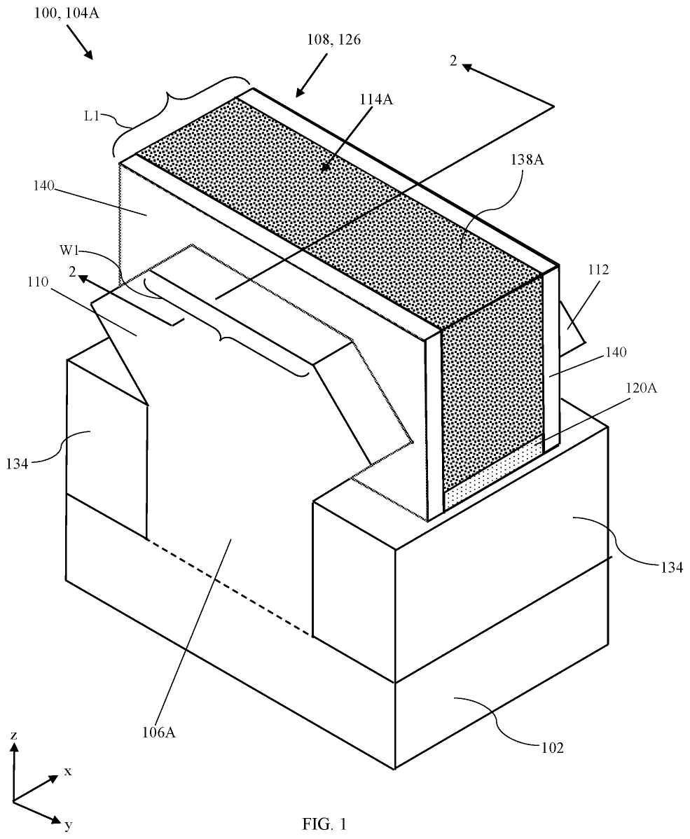

FIG. 1 shows an x-y-z perspective view of a structure 100. Structure 100 may take the form of, or include, any semiconductor or microelectronic device, such transistors, capacitors, resistors, inductors, etc.

Referring to FIGS. 1 and 2-5B, which show structure 100 from various x-y-z partial perspective views or cross-sectional views in the z-x plane, structure 100 may include a substrate 102, as shown in FIGS. 1-5B. Substrate 102 serves as the foundation on, or in, which portions of structure 100 may be manufactured. That is, substrate 102 may provide, e.g., mechanical support to portions of structure 100 thereover. Substrate 102 may include any known or future material capable of being a substrate, including any known or future-discovered semiconductor materials. Substrate 102 may include but is not limited to silicon, germanium, silicon germanium (SiGe), silicon carbide, or any other common integrated circuit (IC) semiconductor substrates. In the case of SiGe, the germanium concentration in substrate 102 may differ from other SiGe-based structures described herein. A portion or entirety of substrate 102 may be strained.

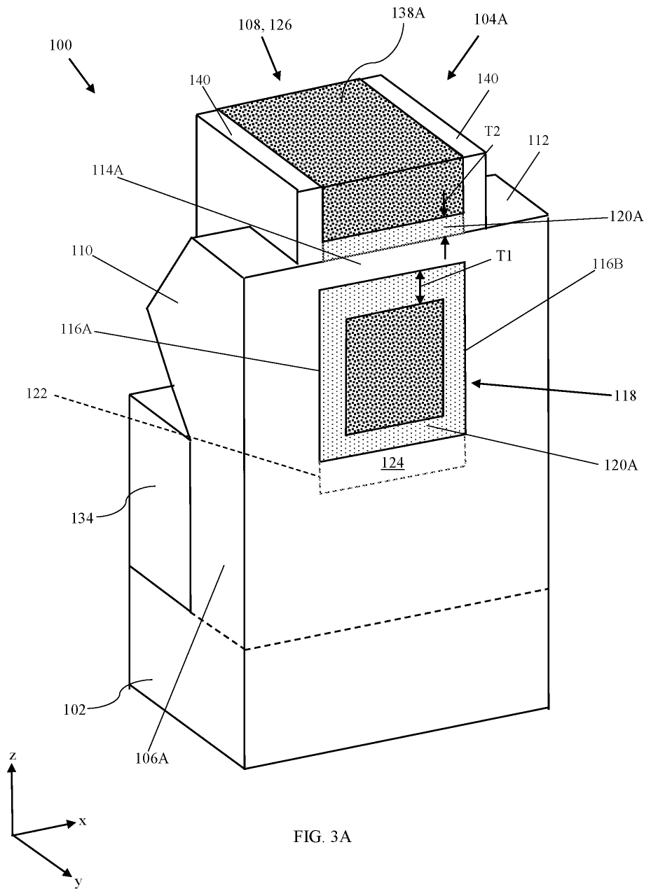

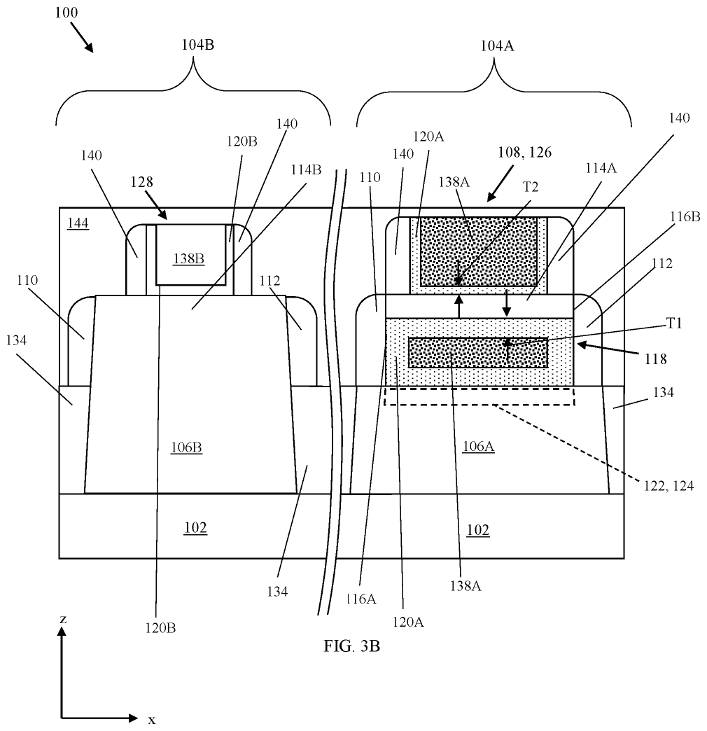

Structure 100 may include a fin-type field effect transistor (finFET) 104 in a semiconductor fin 106. A finFET is a field effect transistor (FET) with a three-dimensional structure, as opposed to the planar structure found in other FET designs. A semiconductor fin is the three-dimensional structure on, or in, which the FET components are integrated. FinFET 104, and therefore semiconductor fin 106, may be on substrate 102 (illustrated as separated by dashed lines for clarity; though, one skilled in the art will appreciate that a boundary may not physically exist) and may serve as part of an electronic circuit (not shown). As described fully herein, finFET 104 may include a gate-all-around (GAA) structure 108 for putting finFET 104 in an operational mode. A gate is a FET terminal that controls the flow of charge carrier (i.e., electrons and holes) between source/drain regions, and, more particularly, a GAA structure surrounds a channel region from all sides, providing even better control (relative to other gate designs) over the flow of charge carriers, as discussed fully herein. In some embodiments, shown in FIGS. 3B, 4B, and 5B, structure 100 may include a second finFET 104B in a second semiconductor fin 106B adjacent finFET 104 (hereinafter “first finFET 104A,” with semiconductor fin 106 therefor hereinafter referred to as “first semiconductor fin 106A”). Break lines between first finFET 104A and second finFET 104B are illustrated in FIGS. 3B, 4B, 5B, and 6A-10C to show that first finFET 104A may not necessarily be adjacent second finFET 104B in structure 100. However, in other implementation, first finFET 104A may be adjacent second finFET 104B. Second finFET 104B may be substantially similar to first finFET 104A, but with a gate structure that does not include gate-all-around architecture, as described fully herein. Although only two finFETs 104A and 104B are illustrated for simplicity, structure 100 may include any number of finFETs.

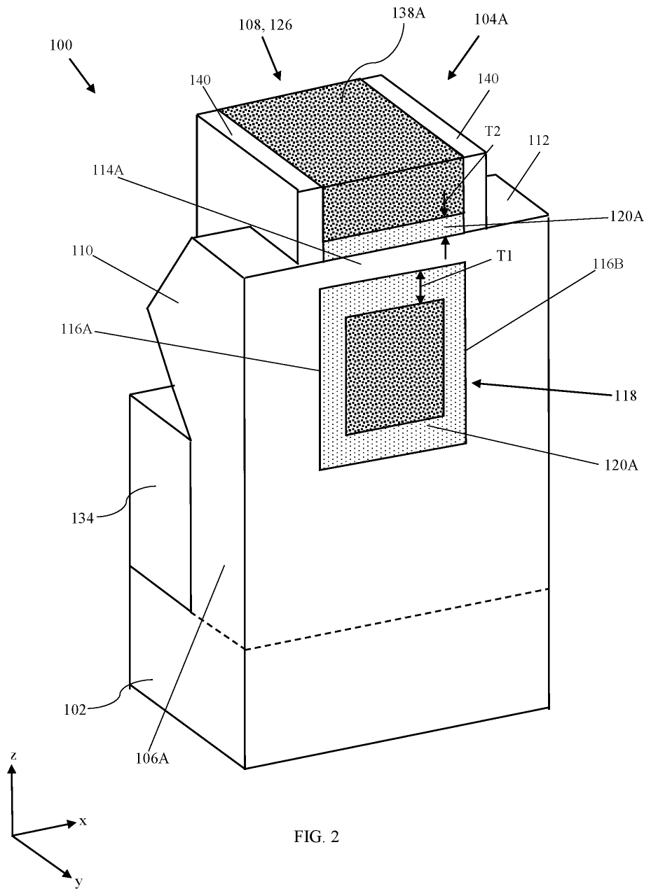

Structure 100 may include a first source/drain (S/D) region 110 and a second S/D region 112 on respective first semiconductor fin 106A in first finFET 104A and second semiconductor fin 106B in second finFET 104B. A source/drain region is a transistor terminal in a FET through which charge carriers flow when the FET is in an operational mode. Here, first S/D region 110 and second S/D region 112 are terminals in respective first finFET 104A and second finFET 104B through which charge carriers flow through a channel region 114 (“channel region 114A” for first finFET 104A and “channel region 114B” in second finFET 104B, respectively) when first finFET 104A and second finFET 104B are in a respective operational mode. Referring to FIGS. 2-3B and 5A-B, first S/D region 110 may be immediately adjacent a first side 116A of a buried gate region 118 of GAA structure 108, and second S/D region 112 may be immediately adjacent a second side 116B of buried gate region 118 of GAA structure 108. As described fully herein, buried gate region 118 is a region of GAA structure 108 that is beneath channel region 114A. First S/D region 110 and second S/D region 112 may include one or more contacts (not shown) immediately thereon to establish electrical communication with other devices or metal layers (not shown) in structure 100. First S/D region 110 and second S/D region 112 may include dopants, i.e., p or n type dopants to enhance electrical conductivity. “Doping” and “dopants” herein refer to altering a semiconductor material's conducting properties by introducing an impurity therein. Different impurities (i.e., different dopants) can be used to achieve different conductivity types (e.g., p type conductivity and n type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve p type conductivity, whereas a silicon-based semiconductor material is typically doped a Group V dopant, such as arsenic (As), phosphorous (P) or antimony (Sb), to achieve n-type conductivity. A gallium nitride (GaN)-based semiconductor material is typically doped with magnesium (Mg) to achieve p-type conductivity and with silicon (Si) or oxygen to achieve n-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

As mentioned, first finFET 104A may include channel region 114 (hereinafter “channel region 114A”) between first S/D region 110 and a second S/D region 112. A channel region is a region within a semiconductor device through which charge carriers flow when the device is in an operational mode (e.g., when a positive voltage is applied to GAA structure 108). For example, in an operational mode, charge carriers may flow from first S/D region 110 through channel region 114A to second S/D region 112. Similarly, second finFET 104B may include a channel region 114 (hereinafter “channel region 114B”) substantially similar to, or even the same as, channel region 114A in first finFET 104A. Channel region 114A and channel region 114B may be, e.g., doped to enhance electrical conductivity therein. In one embodiment, shown in FIG. 1, a width W1 of channel region 114 is at least twice a length L1 of channel region 114. As discussed fully herein, a gate dielectric layer 120A (shown in a light dotted pattern for clarity in FIGS. 1, 2, 3A, 4A, and 5A) in first finFET 104A may surround channel region 114A in GAA structure 108, thereby protecting channel region 114A from hot carrier injection (HCI) from GAA structure 108 as a voltage is applied to GAA structure 108. As discussed previously, HCI is when charge carriers (i.e., electrons or holes) gain sufficient energy to overcome a potential barrier at the interface of two materials (e.g., at the interface of a gate conductor and a dielectric thereunder), which damages the channel region and causes devices to breakdown.

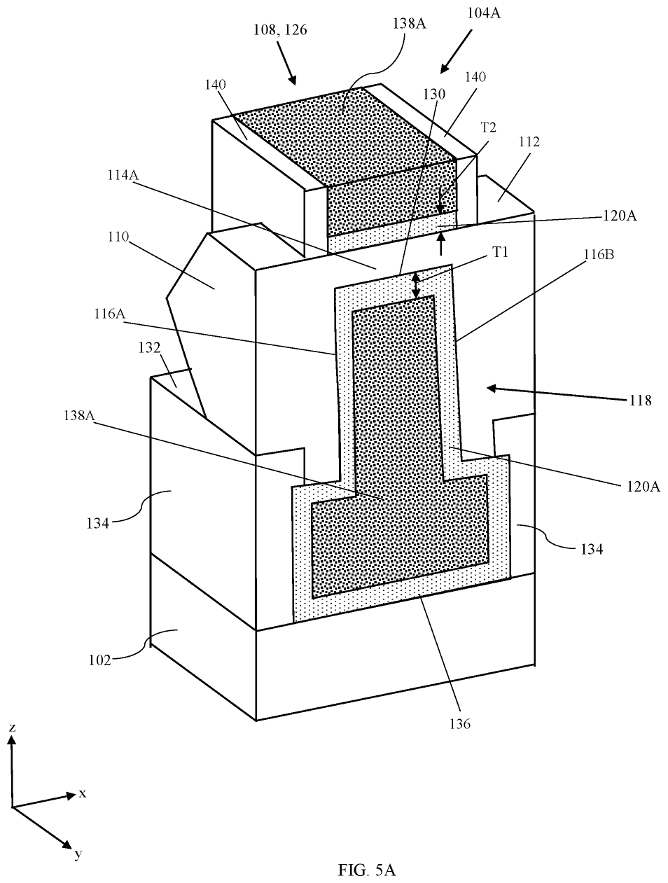

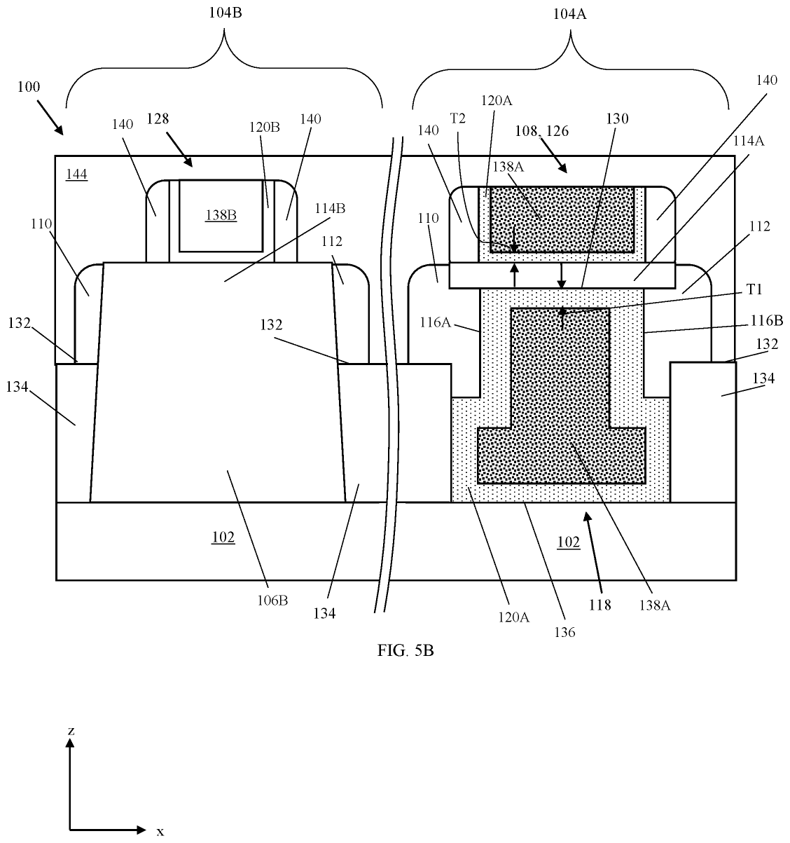

Structure 100 may optionally include a second channel region 122 (illustrated only in FIGS. 3A-B for simplicity, but may, or may not, exist in embodiments shown in FIGS. 1, 2, and 3A-4B) beneath GAA structure 108. Second channel region 122 result as a potential byproduct of the gate-all-around architecture bifurcating part of first semiconductor fin 106A into two conductive portions (i.e., channel region 114A and second channel region 122). Second channel region 122 may be a parasitic (i.e., undesirable) region of charge carrier flow between first S/D region 110 and second S/D region 112. Second channel region 122 may form as a result of the GAA structure 108 and, in particular, the buried gate portion 118, dividing the region between first S/D region 110 and second S/D region 112 in channel region 114A and second channel region 122. When voltage is applied to buried gate portion 118, charge carriers flow through channel region 114A, but may also flow through parasitic channel region 122, thereby pulling charge carriers through a longer path. Embodiments shown in FIGS. 5A-B do not include second channel region 122 because buried gate region 118 extends to substrate 102, thereby eliminating second channel region 122, as discussed fully herein.

To deactivate parasitic second channel region 122 in first finFET 104A, structure 100 may optionally include a highly resistive polysilicon region 124 (illustrated in dashed boxes in FIGS. 3A-B) in first semiconductor fin 106A under buried gate region 118. A highly resistive polysilicon region is a region of disordered crystal lattice material and/or is highly doped to be a poor conductor, i.e., highly resistive polysilicon region is resistive, thereby disrupting charge carrier flow within second channel region 122. The dopant may be selected relative to the transistor majority carrier type to adjust the threshold voltage (“VT”) such that second channel region 122 is effectively “off,” i.e., no charge carriers flow therein.

First finFET 104A may include gate-all-around (GAA) structure 108, which, as discussed previously, is a transistor gate terminal that may surround channel region 114A to control charge carrier flow therein, as described fully herein. When voltage is applied to GAA structure 108, first finFET 104A may be in an operational mode and charge carriers may flow from first S/D region 110 to second S/D region 112 through channel region 114A. As discussed fully herein, GAA structure 108 may include outer gate region 126 over channel region 114A and buried gate region 118 under channel region 114A. GAA structure 108 also surrounds channel region 114A on any sidewalls thereof (not shown). This arrangement is in contrast to a non-gate-all-around gate such as gate 128 (hereinafter “second gate 128”) in second finFET 104B, which is simply over channel region 114B in second finFET 104B. Gate 128 applies voltage to, and controls charge carrier flow in, channel region 114B. GAA structure 108 may include one or more conductive contacts (not shown) thereon to establish electrical communication with other devices or metal layers (not shown) in structure 100.

GAA structure 108 of structure 100 may include an outer gate region 126 over channel region 114A and a buried gate region 118 under of channel region 114A and extending between first S/D region 110 and second S/D region 112 to collectively form GAA structure 108. Outer gate region 126 and buried gate region 118 are part of the gate-all-around design in that outer gate region 126 is above and around channel region 114A, while buried gate region 118 is under channel region 114A (and is, therefore, “buried”). Hence, GAA structure 108 surrounds channel region 114A. Charge carrier flow within channel region 114A may be manipulated by applying voltage to outer gate region 126 and buried gate region 118 to put first finFET 104A in an operational mode. In some embodiments, illustrated in FIGS. 5A-B, buried gate region 118 includes an upper surface 130 above an upper surface 132 of a trench isolation structure 134 and a lower surface 136 in first semiconductor fin 106A below upper surface 130 of TI structure 134. A trench isolation (TI) structure is a region of insulative (i.e., non-electrically-conductive) material, and is discussed fully herein. In those same embodiments, buried gate region 118 may have an upside-down T-shape geometry. The greater surface area of buried gate region 118 decreases resistance within buried gate region 118, thereby increasing charge carrier flow therein. Moreover, embodiments shown in FIGS. 5A-B do not include second channel region 122 because buried gate region 118 extends to substrate 102, thereby eliminating second channel region 122.

Outer gate region 126 and buried gate region 118 (of GAA structure 108) each include a gate metal layer 138 and a gate dielectric layer 120. More particularly, GAA structure 108 of structure 100 may include gate dielectric layer 120A in each outer gate region 126 and buried gate region 118 in first finFET 104A. Gate dielectric layer 120A may “wrap around” channel region 114A to, e.g., electrically insulate and physically protect channel region 114A from HCI from a gate metal layer 138 (i.e., the electrically conductive part of GAA structure 108) therearound. Gate dielectric layer 120A surrounds channel region 114A, as indicated by the light dotted pattern of gate dielectric layer 120A in FIGS. 2-5B. That is, although FIGS. 2-5B show cross-sectional partial perspective views of structure 100 according to various implementations, gate dielectric layer 120A may surround gate metal layer 138A in buried gate region 118 as if gate dielectric layer 120A was coming out of the page and around gate metal layer 138A. In some implementations, gate dielectric layer 120A is thicker in the z- and x-directions in buried gate region 118 than in outer gate region 126. This arrangement protects channel region 114A from HCI from buried gate portion 118 of GAA structure 108. Specifically, as shown in FIGS. 2-5B, gate dielectric layer 120A may include a first thickness T1 in buried region 118 greater than a second thickness T2 in outer gate region 126. Gate dielectric layer 120A may include a high-k dielectric material. Those skilled in the art will recognize that a high-K gate dielectric layer refers to a layer of dielectric material with a dielectric constant that is greater than the dielectric constant of silicon dioxide (i.e., greater than 3.9). Illustrative high-K dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide (zirconium oxide, etc.).

As shown in FIGS. 3B, 4B, and 5B, gate structure 128 in second finFET 104B may also include gate dielectric layer 120B. Gate dielectric layer 120B may be in all aspects similar, or even the same, in function and material composition as gate dielectric layer 120A, but may instead be located vertically between gate structure 128 and channel region 114B to protect channel region 114B from HCI. Gate dielectric layer 120B also has a uniform thickness.

As noted, GAA structure 108 may include a gate metal layer 138 in both outer gate region 126 and buried gate region 118 in first finFET 104A. (Gate metal layer 138 is illustrated with a dark dotted pattern in FIGS. 1-3A. 4A, and 5A to show gate metal layer 138 both in outer gate region 126 and in buried gate region 118). Gate metal layer 138 is the conductive portion of GAA structure 108 which receives an application of voltage from a voltage source (not shown) to put first finFET 104A in an operational mode. Gate metal layer 138A may surround channel region 114A for, e.g., improved control of charge carrier flow within channel region 114A. Gate metal layer 138A may include one or more work function (WF) metals or metal alloy layers and, optionally, a conductive fill material (not shown) on the WF metal or metal alloy layer(s). The WF metal or metal alloy layer(s) can be selected to achieve the optimal WF depending upon the conductivity type of the FET (i.e., optimal NFET WF for an NFET or optimal PFET WF for a PFET). Those skilled in the art will further recognize that the optimal WF for a gate conductor of an NFET will be, for example, between 3.9 eV and about 4.2 eV. Metals (and metal alloys) that have a work function within this range include, but are not limited to, hafnium, zirconium, titanium, tantalum, aluminum, and alloys thereof, such as, hafnium carbide, zirconium carbide, titanium carbide, tantalum carbide, and aluminum carbide. Those skilled in the art will further recognize that the optimal WF for a gate conductor of PFET will be, for example, between about 4.9 eV and about 5.2 eV. Metals (and metal alloys) that have a work function within this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). Alternatively, the WF metal or metal alloy layer(s) can be metal or metal alloy materials that are selected due to suitability for use in either NFETs or PFETs. The optional conductive fill material layer can be, for example, doped polysilicon or any suitable metal or metal alloy fill material including, but not limited to, tungsten, a tungsten alloy (e.g., tungsten silicide or titanium tungsten), cobalt, or aluminum.

As shown in FIGS. 3B, 4B, and 5B, gate structure 128 in second finFET 104B may also include gate metal layer 138B (gate metal layers are hereinafter referred to as “gate metal layer 138A” in first finFET 104A and a “gate metal layer 138B” in second finFET 104B). Gate metal layer 138B may be in all aspects similar, or even the same, in function and material composition as gate metal layer 138A, but may instead be vertically over gate dielectric layer 120B and channel region 114B to apply a voltage to channel region 114B. In contrast to gate metal layer 138A, gate metal layer 138B does not take the form of a gate-all-around architecture and does not surround channel region 114B.

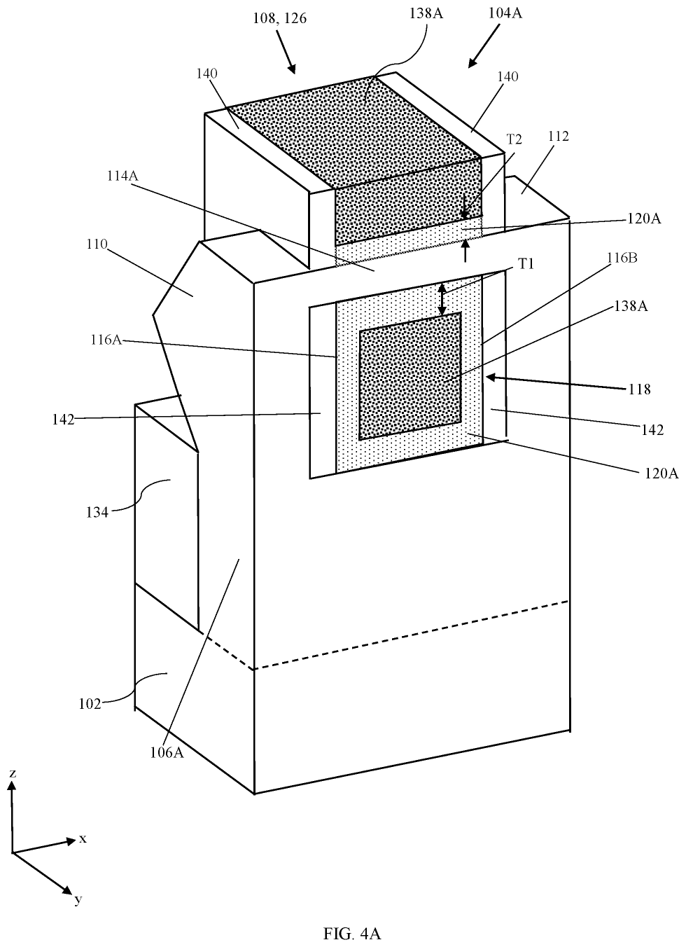

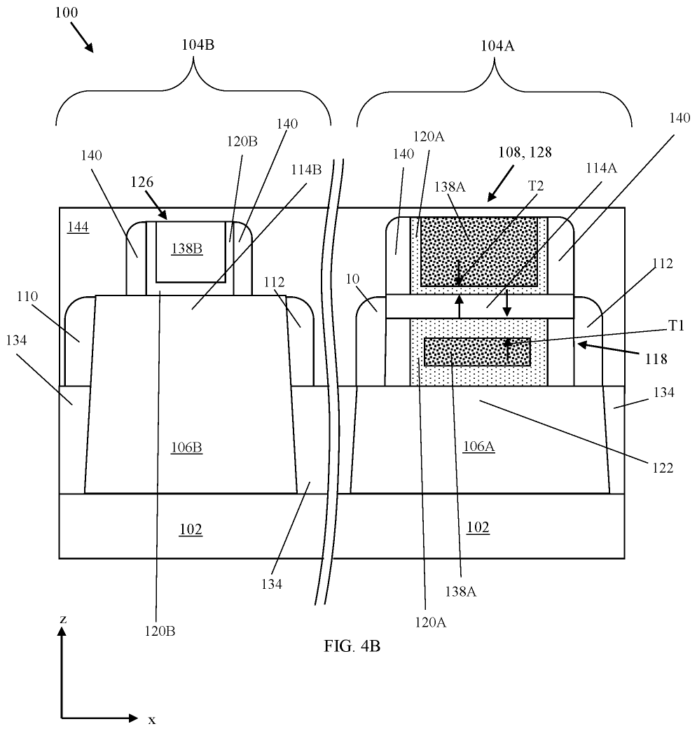

Structure 100 may include spacers 140 between GAA structure 108 and nearby components (e.g., S/D regions 110 and 112) in first finFET 104A, and spacers 140 between outer gate region 126 and nearby components (e.g., S/D regions 110 and 112) in second finFET 104B. A spacer is an insulating material between parts of a gate structure and S/D regions of a transistor, to prevent current leakage therebetween. Here, spacers 140 prevent current leakage between GAA structure 108/gate structure 128 and respective S/D regions 110 and 112. Thus, spacers 140 may include any now known or later developed spacer material such as silicon nitride. Spacers 140 may be substantially similar or even identical between first finFET 104A and in second finFET 104B. In one embodiment, shown in FIGS. 4A-B, first finFET 104A may include optional additional spacers 142 (illustrated in dashed lines to show that additional spacers are optional) between buried gate region 118 and first S/D region 110 and second S/D region 112 in first finFET 104A.

Referring to FIGS. 3A-B, as previously discussed structure 100 may include highly resistive polysilicon region 124 in first semiconductor fin 106A under buried gate region 118 to render second channel region 122 inactive (i.e., non-conductive). Highly resistive polysilicon region 124 may include resistive materials, such as polycrystalline silicon (also called “polysilicon”). Because of the relatively high resistance of highly resistive polysilicon region 124, second channel region 122 will not conduct charge carriers therein.

As shown in FIGS. 3B and 4B, structure 100 may further include trench isolation (TI) structure 134 adjacent first semiconductor fin 106A. Generally, a trench isolation structure is a trench etched in a substrate and filled with an insulating material such as oxide, to isolate one region of structure 100 from an adjacent region of structure 100. Structure 100 may include multiple TI structures 134, including TI structures 134 between first finFET 104A and second finFET 104B, or on either sides of finFETs 104A-B, as shown in FIGS. 3B, 4B, and 5B. Each TI structure 134 may include any currently-known or later developed substance for providing electrical insulation, and as examples may include: silicon nitride (Si3N4), silicon oxide (SiO2), fluorinated SiO2 (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, near frictionless carbon (NFC), or layers thereof. In some embodiments, illustrated in FIGS. 5A-B, buried gate region 118 includes an upper surface 130 above an upper surface 132 of TI structure 134 and a lower surface 136 in first semiconductor fin 106A below upper surface 132 of TI structure 134.

Structure 100 may include an inter-layer dielectric (ILD) layer 144 over first finFET 104A and second finFET 104B, as shown in FIGS. 3B, 4B, and 5B. ILD layer 144 may an insulative material used in semiconductor device manufacturing to electrically, thermally, or physically insulate/isolate different layers of electronic components in an IC. Suitable dielectric materials include but are not limited to: carbon-doped silicon dioxide materials; fluorinated silicate glass (FSG); organic polymeric thermoset materials; silicon oxycarbide; SiCOH dielectrics; fluorine doped silicon oxide; spin-on glasses; silsesquioxanes, including hydrogen silsesquioxane (HSQ), methyl silsesquioxane (MSQ) and mixtures or copolymers of HSQ and MSQ; benzocyclobutene (BCB)-based polymer dielectrics, and any silicon-containing low-k dielectric. Examples of spin-on low-k films with SiCOH-type composition using silsesquioxane chemistry include HOSP™ (available from Honeywell), JSR 5109 and 5108 (available from Japan Synthetic Rubber), Zirkon™ (available from Shipley Microelectronics, a division of Rohm and Haas), and porous low-k (ELk) materials (available from Applied Materials). Examples of carbon-doped silicon dioxide materials, or organosilanes, include Black Diamond™ (available from Applied Materials) and Coral™ (available from Lam Research). An example of an HSQ material is FOx™ (available from Dow Corning).

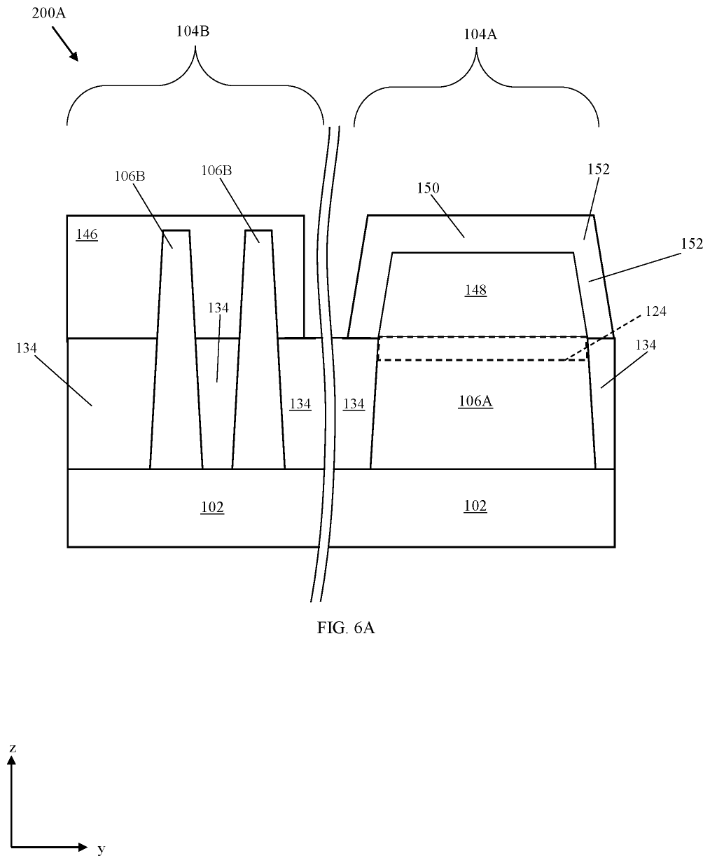

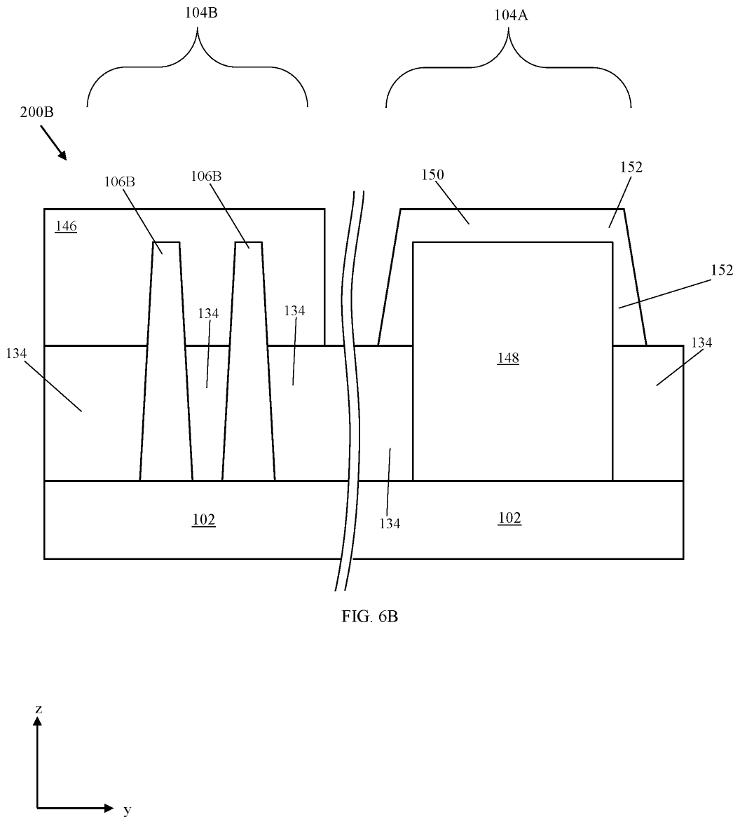

Embodiments of the disclosure provide methods to form a structure according to various embodiments. FIGS. 6A-10C show cross-sectional views of a structure at various stages of fabrication.

FIGS. 6A-B shows a preliminary structure 200A and a preliminary structure 200B in the z-y plane after formation of first semiconductor fin 106A and second semiconductor fins 106B, according to implementations of this disclosure. Embodiments of a method may include forming first semiconductor fin 106A and second semiconductor fins 106B by, e.g., etching portions of substrate 102. “Etching” generally refers to the removal of material from a substrate (or structures formed on the substrate), and is often performed with a mask in place so that material may selectively be removed from certain areas of the substrate, while leaving the material unaffected, in other areas of the substrate. There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g. silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases which approach the wafer approximately from one direction, and therefore this process is highly anisotropic. Reactive-ion etching (RIE) operates under conditions intermediate between sputter and plasma etching and may be used to produce deep, narrow features, such as TI trenches.

Embodiments of a method may include forming first finFET 104A in first semiconductor fin 106A. In some embodiments, shown in FIG. 6A-B, methods described herein may include forming second finFET 104B in second semiconductor fins 106B adjacent first finFET 104A. Forming second finFET 104B in second semiconductor fins 106B may include substantially similar steps to forming first finFET 104A except without forming GAA structure 108, as described fully herein.

Embodiments of a method may include forming optional highly resistive polysilicon region 124 within first semiconductor fin 106A, in an embodiment shown in FIG. 6A (highly resistive polysilicon region 124 is illustrated in dashed lines throughout to show that it is optional). As previously discussed, highly resistive polysilicon region 124 may be formed of resistive materials, such as polycrystalline silicon. Alternatively, as shown in FIG. 6B, methods may not include forming optional highly resistive polysilicon region 124. Highly resistive polysilicon region 124 may be formed by, e.g., doping, or depositing resistive materials on, a portion of first semiconductor fin 106A. “Depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

Embodiments of a method may include forming a mask 146 over second finFET 104B to protect second finFET 104B to prevent further processing to second finFET 104B. The term “mask” may be given to a layer of material which is applied over an underlying layer of material, and patterned to have openings, so that the underlying layer can be processed where there are openings. After processing the underlying layer, the mask may be removed. Common masking materials are photoresist (resist) and nitride. Nitride is usually considered to be a “hard mask.” Mask may include a developable organic planarization layer (OPL) on the layer to be etched, a developable anti-reflective coating (ARC) layer on the developable OPL, and a photoresist mask layer on the developable ARC layer. Masks may be removed using any known removal process appropriate for the mask material, e.g., a wet etch for hard nitride mask or an ashing process (oxygen dry strip process) for a soft resist-based mask.

Embodiments of a method may include performing an etch step to remove a portion first semiconductor fin 106A, which results in either a partial etch (i.e., not fully to substrate 102) shown in FIG. 6A or the full etch (i.e., fully etching second semiconductor fin 104B to substrate 102) shown in FIG. 6B, to make space for a sacrificial layer 148 in subsequent processing, as described fully herein.

Embodiments of a method may include forming a sacrificial layer 148 over first semiconductor fin 106A (FIG. 6A) or over substrate 102 (FIG. 6B). Sacrificial layer 148 is removed in subsequent processing to make space for formation of buried gate region 118. Sacrificial layer 148 may be deposited or epitaxially grown. The terms “epitaxial growth” and “epitaxially formed and/or grown” mean the growth of a semiconductor material on a deposition surface of a semiconductor material, in which the semiconductor material being grown may have the same crystalline characteristics as the semiconductor material of the deposition surface. In an epitaxial growth process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a {100} crystal surface may take on a {100} orientation. In some embodiments, epitaxial growth processes may be selective to forming on semiconductor surfaces, and may not deposit material on dielectric surfaces, such as silicon dioxide or silicon nitride surfaces.

Embodiments of a method may include forming a channel region layer 150 over sacrificial layer 148. Channel region layer 150 is a layer of conductive material and may be converted into channel region 114A through subsequent processing, as described fully herein. In some implementations, channel region layer 150 may be formed conformally over sacrificial layer 148 by, e.g., deposition or epitaxial growth. The conformal process may create side portions 152 around sacrificial layer 150.

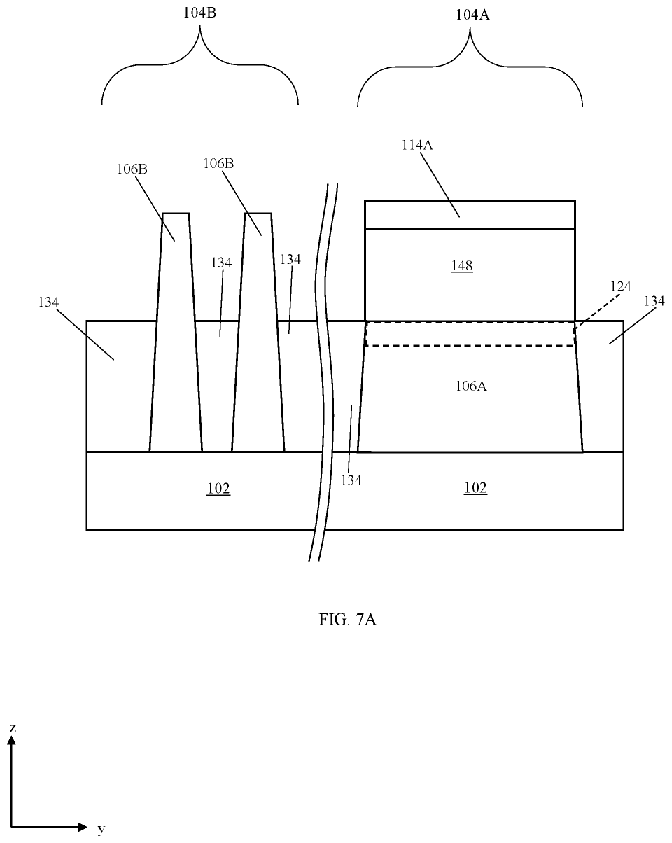

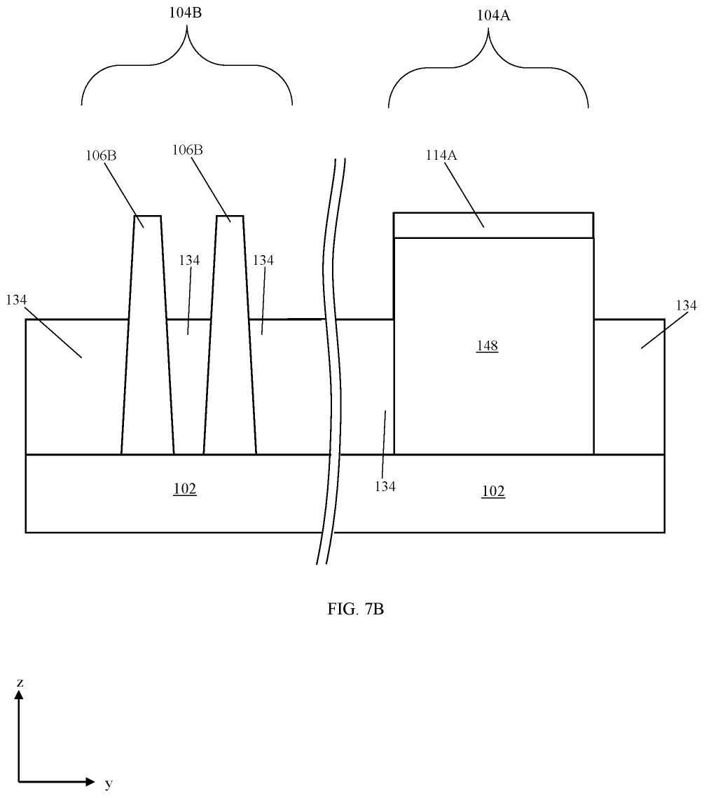

Referring now to FIGS. 7A-B, which shows embodiments of a method in the z-y plane. Here, embodiments of a method may include removing side portions 152 of channel region layer 150 by, e.g., etch, thereby creating channel region 114A. Thereafter, mask 146 may be removed via etch to make space for subsequent processing in second finFET 104B.

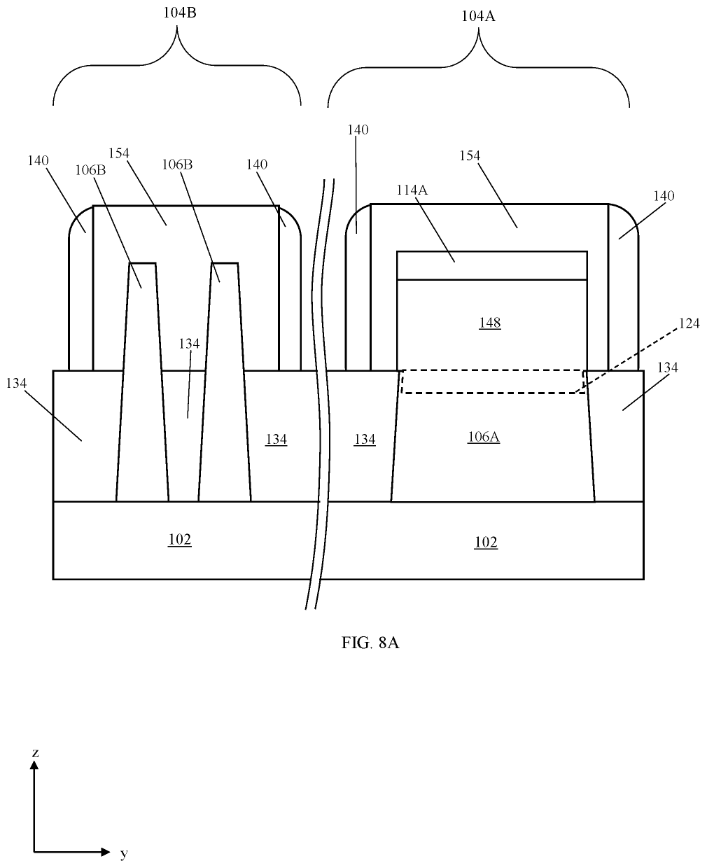

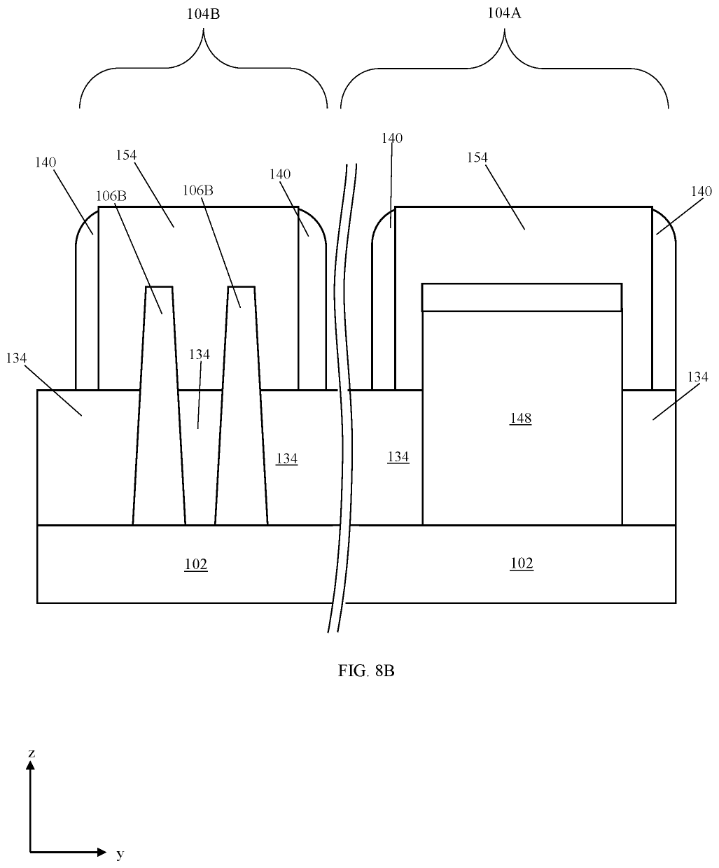

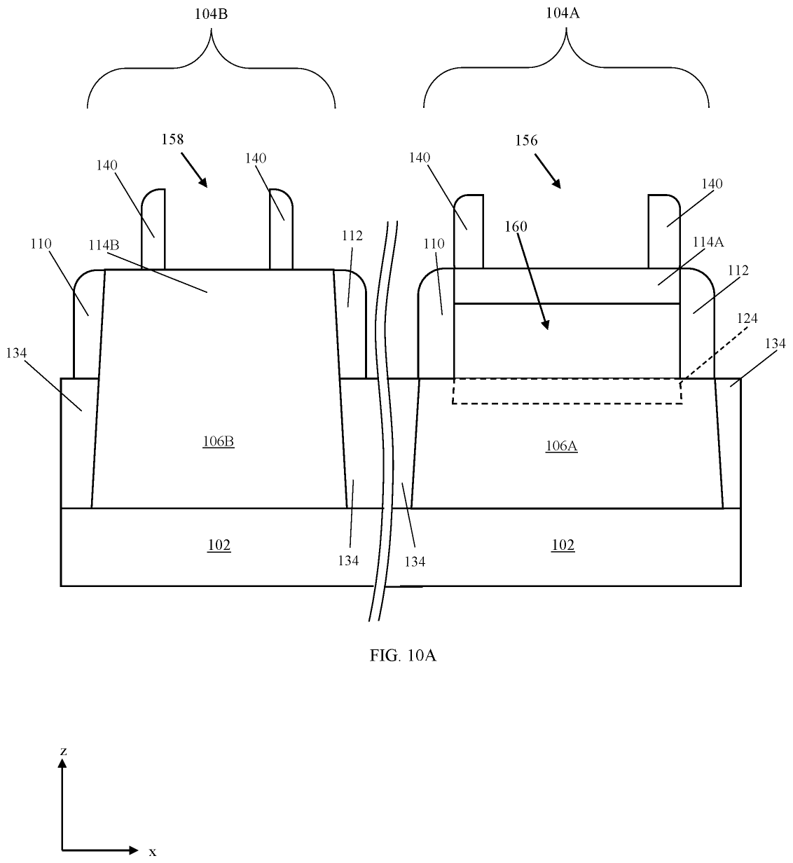

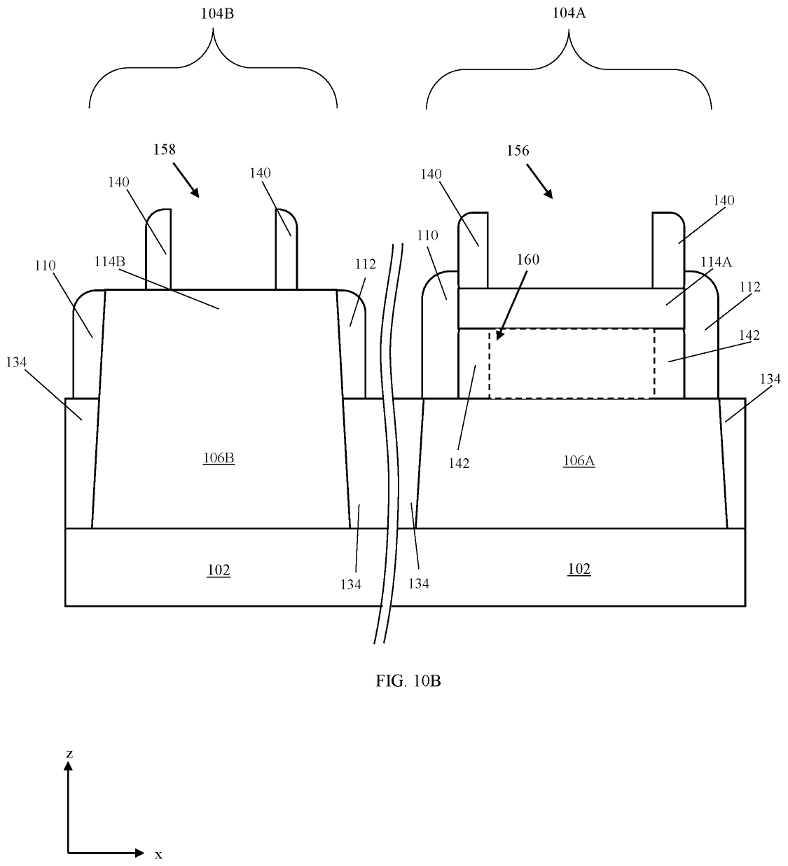

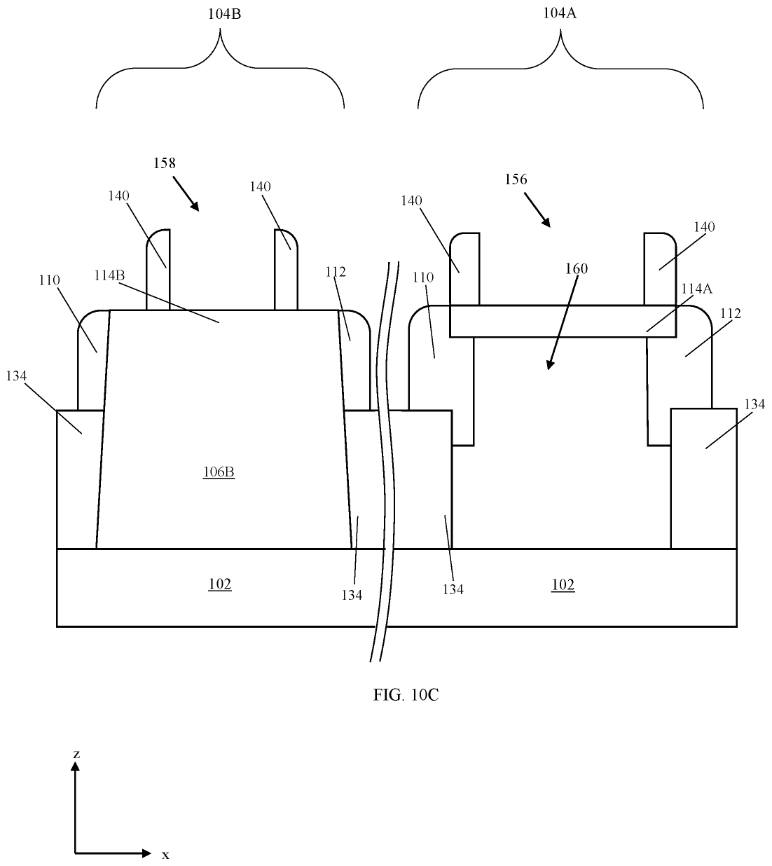

Referring now to FIGS. 8A-B, which shows methods described herein in the z-y plane, embodiments of a method may include forming a sacrificial polysilicon gates 154 over both finFETs 104A-B. Sacrificial polysilicon gates 154 may be formed as part of a replacement metal gate (RMG) process, which include forming sacrificial polysilicon gates 154 (FIGS. 8A-B), forming spacers 140 on vertical side surfaces of sacrificial polysilicon gates 154 over both finFETs 104A-B by, e.g., deposition (also shown in FIGS. 8A-B), and removing sacrificial polysilicon gates 154 (FIGS. 10A-B) to make space for gate dielectric layers 120A-B and gate metal layers 138A-B, as discussed fully herein. Sacrificial polysilicon gate 154 may be formed by, e.g., deposition.

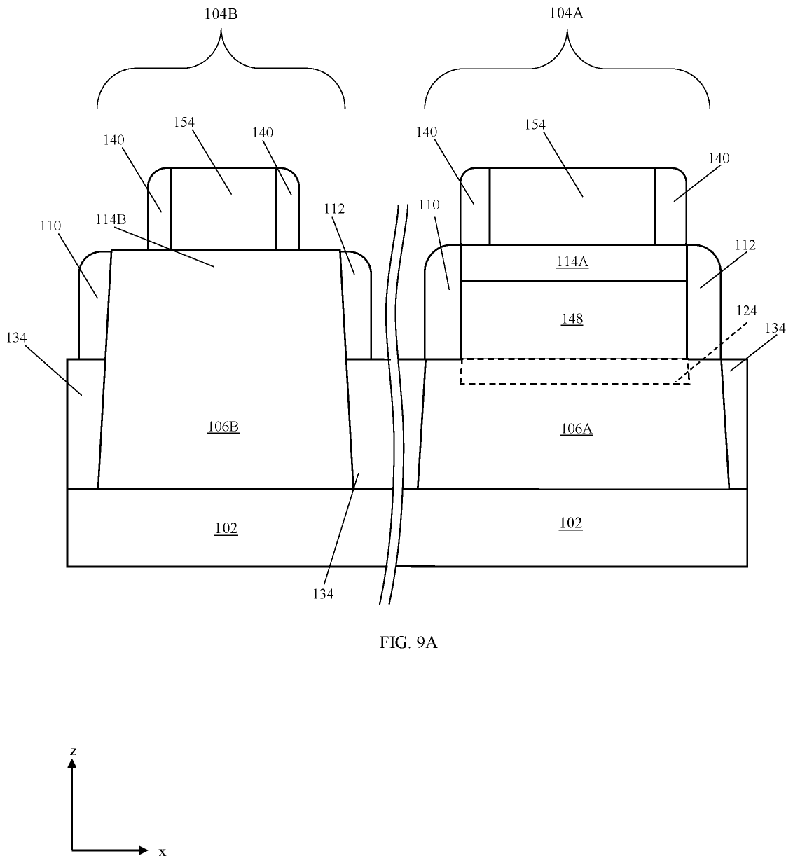

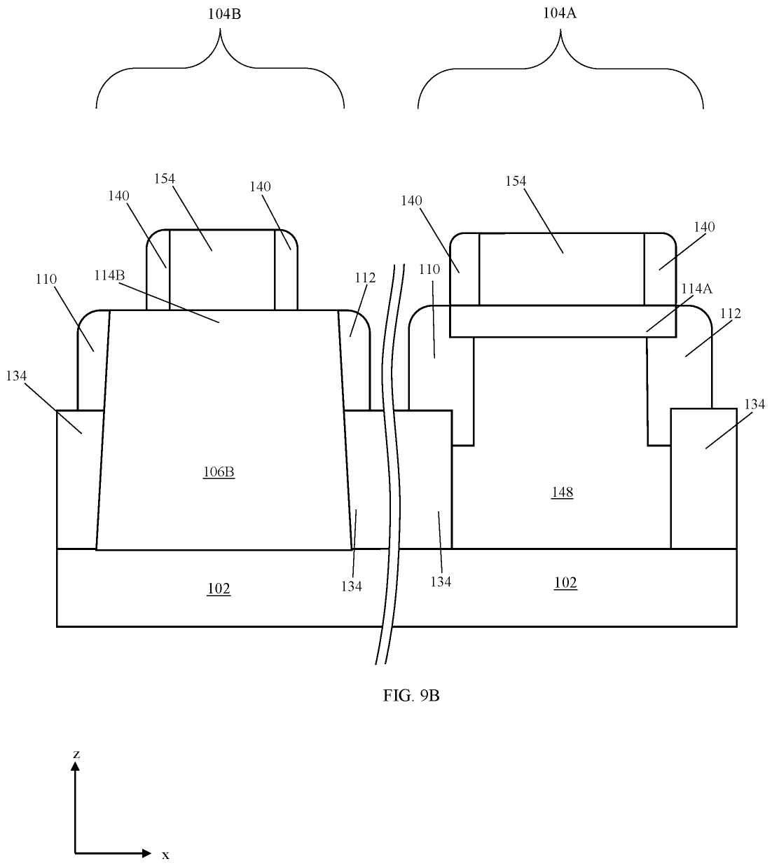

Referring now to FIGS. 9A-B, which show embodiments of a method may in the z-x plane, the method may include forming first S/D regions 110 and second S/D regions 112 on respective semiconductor fin 106A and second semiconductor fin 106B by, e.g., deposition or epitaxial growth such that channel regions 114A and 114B may be between respective first S/D region 110 and second S/D region 112. As shown in FIG. 9A, sacrificial polysilicon gate 154 and spacers 140 are over channel region 114A in first finFET 104A, and sacrificial polysilicon gate 154 and spacers 140 are over channel region 114B in second finFET 104B. In an embodiment shown in FIG. 9B, S/D regions 110 and 112 may be similarly formed along sidewalls of sacrificial layer 148 that extends to substrate 102.

Referring to FIGS. 10A-C, which show embodiments of the method in the z-x plane. Here, embodiments of the method may include removing sacrificial layer 148 and removing sacrificial polysilicon gate 154 by, e.g., etch, thereby leaving gap 156 which will be filled with gate dielectric layer 120A and gate metal layer 138A to form buried gate portion 118 in first finFET 104A in subsequent processing. In second finFET 104B, also shown in FIGS. 10A-C, gate dielectric layer 120B and gate metal layer 138B may be formed in gap 158 between spacers 140. Additionally, removal of sacrificial layer 148 results in gap 160 under channel region 114A in first finFET 104A, the removal of which makes space for formation of buried gate region 118 in subsequent processing. In FIG. 10C, gap 160 may extend to substrate 102 to make space for buried gate region 118, which may be formed extending from channel region 114B to substrate 102.

In one embodiment, shown in FIG. 10B, embodiments of a method may include forming additional spacers 142 under channel region 114A by, e.g., depositing insulative material under channel region 114A.

Referring to completed structures in FIGS. 3B, 4B, and 5B, embodiments of the method may include forming gate dielectric layer 120A in first finFET 104B by, e.g., depositing insulative material over channel region 114A (in outer gate region 126) and within gap 158 (in buried gate region 118), and forming gate dielectric layer 120B in second finFET 104B may include depositing insulative material over second semiconductor fin 106B. In FIGS. 3B and 4B, gate dielectric layer 120A may be formed along interior of gap 160. In particular, forming outer gate region 126 and buried gate region 118 may include forming gate dielectric layer 120A surrounding channel region 114A. In the embodiment shown in FIG. 3B in particular, gate dielectric layer 120A is formed over highly resistive polysilicon region 124. In the embodiment shown in FIG. 4B, gate dielectric layer 120A is formed along interior of gap 160 and over sidewalls of additional spacers 142. In the embodiment shown in FIG. 5B, gate dielectric layer 120A is formed along the sidewalls of gap 160 to form an upside T-shape. That is, buried gate region 118 may be formed to extend from channel region 114A to substrate 102. In FIGS. 3B, 4B, and 5B, gate dielectric layer 120B may be formed over channel region 114B in second finFET 104B. As previously described, gate dielectric layer 120A may be formed to be thicker in buried gate region 118 than in outer gate region, as shown in FIG. 3B. In all embodiments, gate dielectric layer 120B is formed over channel region 114B in second finFET 104B.

Embodiments of a method may include forming gate metal layer 138A in first finFET 104B by, e.g., depositing conductive metal material over gate dielectric layer 120A in outer gate region 126 and buried gate region 118 to arrive at outer gate region 126 over channel region 114A and buried gate region 118 under channel region 114A and extending between first S/D region 110 and second S/D region 112 of first finFET 104A. Similarly, in second finFET 104B, gate dielectric layer 138B may be formed over channel region 114B by, e.g., deposition.

Embodiments of a method may include forming ILD 144 over first finFET 104A and second finFET 104B by, e.g., depositing insulative material thereover, to electrically isolate first finFET 104A and second finFET 104B from one another and other devices in structure 100.

Embodiments of the disclosure include a gate-all-around structure 108 including a gate dielectric layer 120A that is thicker in a buried gate region 118 than in an outer gate region 126 thereover. By including a thicker gate dielectric layer 120A in buried gate region 118, first finFET 104A may experience less hot carrier injection in channel region 114A than similar devices, such as second finFET 104B. By experiencing less hot carrier injection in channel region 114A, structure 100 may have improved device reliability and longevity.

The method and structure as described above are used in the fabrication and operation of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure, comprising:
a first fin-type field effect transistor (finFET) in a first semiconductor fin, the first finFET including:
a channel region between a first source/drain (S/D) region and a second S/D region; and
a gate all around (GAA) structure including:
an outer gate region over the channel region and a buried gate region under of the channel region and extending between the first S/D region and the second S/D region, the outer gate region and the buried gate region each including a gate metal layer and a gate dielectric layer,
wherein the gate dielectric layer is thicker in the buried gate region than in the outer gate region.

2. The structure of claim 1, wherein a width of the channel region is at least twice a length of the channel region.

3. The structure of claim 1, wherein the gate dielectric layer surrounds the channel region.

4. The structure of claim 3, wherein the gate dielectric layer surrounds the gate metal layer in the buried gate region.

5. The structure of claim 1, further comprising a second finFET in a second semiconductor fin adjacent the first finFET.

6. The structure of claim 1, wherein the first S/D region is immediately adjacent a first side of the buried gate region, and the second S/D region is immediately adjacent a second side of the buried gate region.

7. The structure of claim 1, wherein the GAA structure further includes a spacer between the buried gate region and the first source/drain region and the second source/drain region.

8. The structure of claim 1, further comprising a highly resistive polysilicon region in the first semiconductor fin under the buried gate region.

9. The structure of claim 1, further comprising a trench isolation structure adjacent the first semiconductor fin, wherein the buried gate region has an upper surface above an upper surface of the trench isolation structure and a lower surface in the first semiconductor fin below the upper surface of the trench isolation structure.

10. The structure of claim 1, wherein the channel region in a sole channel region in the first finFET.

11. A structure, comprising:
a first fin-type field effect transistor (finFET) in a first semiconductor fin, the first finFET including:
a single channel region between a first source/drain (S/D) region and a second S/D region;
a gate all around (GAA) structure including an outer gate region over the channel region and a buried gate region under of the channel region and extending between the first S/D region and the second S/D region, the outer gate region and the buried gate region each including a gate metal layer and a gate dielectric layer,
wherein the gate dielectric layer is thicker in the buried gate region than in the outer gate region, and
a second finFET in a second semiconductor fin adjacent the first finFET.

12. The structure of claim 11, wherein a width of the single channel region is at least twice a length of the single channel region.

13. The structure of claim 11, wherein the first S/D region is immediately adjacent a first side of the buried gate region, and the second S/D region is immediately adjacent a second side of the buried gate region.

14. The structure of claim 11, wherein the GAA structure further includes a spacer between the buried gate region and the first S/D region and the second S/D region.

15. The structure of claim 11, further comprising a highly resistive polysilicon region in the first semiconductor fin under the buried gate region.

16. The structure of claim 11, further comprising a trench isolation structure adjacent the first semiconductor fin, wherein the buried gate region has a lower surface in the first semiconductor fin below an upper surface of the trench isolation structure.

17. A method, comprising:
forming a first semiconductor fin; and
forming a first fin-type field effect transistor (finFET) in the first semiconductor fin, including:
forming a channel region between a first source/drain (S/D) region and a second S/D region;
forming a gate all around (GAA) structure, including:
forming an outer gate region over the channel region and a buried gate region under of the channel region and extending between the first S/D region and the second S/D region,
forming a gate dielectric layer surrounding the channel region, wherein the gate dielectric is thicker in the buried gate region than in the outer gate region, and
forming a gate metal layer surrounding the gate dielectric layer about the channel region.

18. The method of claim 17, wherein the gate dielectric layer surrounds the gate metal layer in the buried gate region.

19. The method of claim 17, wherein the gate dielectric surrounds the gate metal layer in the buried gate region.

20. The method of claim 17, further comprising forming a second finFET in a second semiconductor fin adjacent the first finFET.
